(19) United States
(12) Patent Application Publication
(10) Pub. No.: US 2025/0169260 A1
(43) Pub. Date: May 22, 2025

(54) METHOD FOR PRODUCING AN ARRAY OF LIGHT EMITTING ELEMENTS AND DISPLAY

(71) Applicant: Ams-OSRAM International GmbH, Regensburg (DE)

(72) Inventors: Tansen Varghese, Regensburg (DE); Adrian Stefan Avramescu, Regensburg (DE)

(21) Appl. No.: 18/832,434

(22) PCT Filed: Jan. 17, 2023
(86) PCT No.: PCT/EP2023/050949

§ 371 Date: Jul. 23, 2024

(30) Foreign Application Priority Data
Jan. 26, 2022 (DE) 10 2022 101 810.5

(51) Int. Cl. H10H 29/01; H10H 29/37; H10H 29/855

(52) U.S. Cl. CPC H10H 29/012; H10H 29/011; H10H 29/37; H10H 29/855

(57) ABSTRACT

In an embodiment a method for producing an array of light emitting elements includes providing a growth substrate, applying a mask having a plurality of apertures to the growth substrate, growing structures into the apertures and processing at least some of the structures into light emitting elements, wherein adjacent apertures are arranged at a first distance to each other, wherein adjacent light emitting elements are arranged at a second distance to each other, wherein the second distance is greater than the first distance, wherein at least some of the structures are reduced in an area and the reduced structures are processed into light emitting elements, and wherein the structures are reduced in area by material removal.

### CROSS-REFERENCE TO RELATED APPLICATIONS

This patent application is a national phase filing under section 371 of PCT/EP2023/050949, filed Jan. 17, 2023, which claims the priority of German patent application 102022101810.5, filed Jan. 26, 2022, each of which is incorporated herein by reference in its entirety.

### TECHNICAL FIELD

A method of producing an array of light emitting elements is specified. Further a display device is specified.

### SUMMARY

Embodiments provide an enhanced method for producing an array of light emitting elements. Further embodiments provide a display device which can be produced with such a method.

According to one aspect of the method, a growth substrate is provided. The growth substrate is, for example, given by a wafer which comprises or consists of one of the following materials: GaAs, sapphire, silicon, SiC, GaN, AlN. Thereby it is possible that the growth substrate is formed by a single crystal. Alternatively, the growth substrate can comprise a plurality of layers made from different materials like GaAs, sapphire, silicon, SiC, GaN, and/or AlN.

The growth substrate comprises a growth surface which is formed by an outer surface of the growth substrate. Semiconductor layers can be applied onto the growth surface, for example by epitaxial growth.

According to at least one aspect of the method a mask having a plurality of apertures is applied to the growth substrate. For example, the mask is applied to the growth surface of the growth substrate. The mask can be in direct contact with the growth substrate. The mask is formed from a material which is different from the material of the underlying growth substrate. For example, the mask is formed with materials like SiO₂ or SiN.

The mask has a plurality of apertures. In the apertures the growth substrate is not covered by material of the mask and the growth substrate is accessible for, for example, epitaxial growth onto the growth substrate. In this way the apertures are openings of the mask material in which the growth substrate is freely accessible. The apertures or openings of the mask can all have the same size and the same shape. Further, it is possible that the mask comprises apertures of different size and/or shape.

According to at least one aspect of the method, structures are grown into the apertures onto the growth substrate. The structures are, for example, formed by different semiconductor materials. For example, the structures are epitaxially grown into the apertures. The structures, for example, comprise p-doped and n-doped layers. Further, the structures can comprise at least one active layer which is arranged between the doped layers.

According to at least one aspect of the method, at least some of the structures are processed into light emitting elements. Thereby it is also possible that all of the structures are processed into light emitting elements.

Each light emitting element, for example, forms a light emitting diode or a laser diode. The light emitting elements are configured to emit electromagnetic radiation, for example in the spectral range from infrared radiation through UV radiation, in particular visible light.

Different light emitting elements which derive from different structures can be configured to emit electromagnetic radiation of the same or a different spectral range. For example, all light emitting elements can be configured to emit light of the same color or only some of the light emitting elements are configured to emit light of a first color and some of the light emitting elements are configured to emit light of a second color or a third color and so on.

The processing of at least some of the structures into light emitting elements can, for example, be done by providing electrical contacts for contacting the light emitting elements.

According to at least one aspect of the method, adjacent apertures are arranged at a first distance to each other. For example, all apertures can be arranged at the first distance to their adjacent apertures. Thereby the first distance is, for example, given by the distance between edges of adjacent structures which face each other.

According to at least one aspect of the method of producing an area of light emitting elements, adjacent light emitting elements are arranged at a second distance to each other. The second distance is, for example, measured by the distance between facing edges of the light emitting elements.

According to at least one aspect of the method of producing an array of light emitting elements, the second distance is greater than the first distance. That is to say, the distance between the light emitting elements is greater than the distance between the apertures into which the light emitting elements are grown.

According to at least one aspect of the method, the method comprises:
providing a growth substrate,
applying a mask having a plurality of apertures to the growth substrate,
growing structures into the apertures,
processing at least some of the structures into light emitting elements, wherein
adjacent apertures are arranged at a first distance to each other,
adjacent light emitting elements are arranged at a second distance to each other, and
the second distance is greater than the first distance.

Thereby the method can be performed in the given sequence or in another sequence.

The method described here is based on the following considerations, among others: Growing of structures into apertures of a mask, which can also be denoted as “selective area growth”, can be used to define LEDs or VCSELs and other devices such as nanorod devices. For example, InGaN-based micro-LEDs can be grown using selective area growth to obtain different wavelengths by varying the size of the mask apertures or to obtain higher relaxation in order to incorporate more indium to obtain long wavelengths by reducing the size of the apertures.

One problem when growing the structures into the apertures of a mask is so-called parasitic growth, which is growth of material on the mask outside of the apertures. This causes problems such as leakage current, shorting of the growth structures and emission of unsuitable wavelengths. One method to reduce the influence of parasitic growth is to dry etch or wet etch the parasitic growth residues after the growth of the structures is completed. Thereby the structures have to be protected from the etching agent. This requires careful alignment and very high resolution of the lithography when forming a mask for etching. Further, the etching of the residues is frequently not perfect and residues remain.

One idea of the present method is to reduce or avoid parasitic growth during the growth of the structures. For this the area of the selective area mask is minimized by minimizing the distance between adjacent apertures of the mask. By reducing the first distance, i.e. the distance between adjacent apertures, the area of the mask onto which the parasitic growth takes place is reduced. By this the parasitic growth is reduced as the selectively grown area fraction of the aperture is larger, due to gas flow and species mobility dynamics.

According to at least one aspect of the method, only some of the structures are processed into light emitting elements. That is to say, not all of the structures are processed into light emitting elements, but only selected structures which, for example, have the wanted distance to each other are processed into light emitting elements.

For example, the structures are grown at half or another fraction of the pitch which is wanted for the light emitting elements. Only structures which are in the correct pitch with respect to each other are processed completely. The structures in between are, for example, not contacted and/or processed to different elements which are not configured to emit light.

According to at least one aspect of the method, at least some of the structures are reduced in area and the reduced structures are processed into light emitting elements. Thereby structures are, for example, grown with a greater area than the target area of the final light emitting elements. These structures are then subject to processing such as etching, partial optical blocking or other techniques to obtain light emitting structures of the correct width and with the correct second distance to each other.

According to at least one aspect of the method, two or more of the structures are combined to form one of the light emitting elements. That is to say, the light emitting elements are formed by processing groups of the structures into the larger light emitting elements which are larger than a single structure.

The two or more structures which are combined to form such a light emitting element then, for example, form a sub-pixel of the light emitting element. Thereby, it is possible that all structures of the light emitting element emit electromagnetic radiation in the same spectral range or it is possible that different structures of one light emitting element emit light in different wavelength ranges.

For example, a first structure can be configured to emit blue light, a second structure can be configured to emit red light and a third structure can be configured to emit green light. Further combinations of structures with the same or other colors are also possible.

According to at least one aspect of the method, at least one of the structures which is not processed into a light emitting element is arranged between two adjacent light emitting elements.

That is say, for example a non-contact structure is arranged between two adjacent light emitting elements and therefore the distance between the two light emitting elements is, for example, greater than the width of the structure arranged between the light emitting elements.

In this way only certain structures are chosen to be the light emitting elements out of the array of all structures formed during growth. These light emitting elements have the correct size and pitch and the other structures are arranged between those light emitting elements.

According to at least one aspect of the method, at least one of the structures which is not processed into light emitting elements is processed into a light detecting element. In this way the structure is, for example, used to monitor light emitting elements adjacent to it. For example, the structure is processed to be a photodiode.

According to at least one aspect of the method, at least one of the structures which is not processed into a light emitting element is processed into a non-optical electronic element. For example, the non-optical electronic element is configured for switching one or more of the light emitting elements. For example, such a non-optical electronic element can be a high-electron-mobility transistor or another kind of field-effect transistor.

According to at least one aspect of the method, structures which are not processed into a light emitting element are grown into further apertures of the mask with greater areas than the apertures of the mask into which structures are grown which are processed into light emitting elements. That is to say, there are mask apertures with different shapes and sizes for structures which are not intended to be processed into light emitting elements than for structures which are processed into light emitting elements.

Further a display device is specified. For example, the display device comprises a plurality of light emitting elements and can be produced using the here described method. Accordingly, all features of the method are also disclosed for the display device and vice versa.

According to one aspect the display device comprises a plurality of light emitting elements and structures having a similar or the same composition as the light emitting elements wherein the structures are not configured to emit light and at least one of the structures is arranged between light emitting elements.

As explained above, the structures are grown onto a common growth substrate and only some of the structures can be further processed into light emitting elements. As a result, the structures and the light emitting elements which are grown during the same growth process comprise a similar or the same composition, for example of the semiconductor layer sequence which is part of the structures and the light emitting elements.

Alternatively or at the same time, at least some of the light emitting elements have a reduced area due to a material removal. That is to say, it is possible that for some or all of the light emitting elements the area is reduced due to a material removal. As a result, the light emitting elements, for example, show traces of such a removal process, such as for example traces of an etching process.

Further, as an alternative or at the same time, at least some of the light emitting elements are partially covered by a light reflecting or absorbing material. Such light emitting elements are not subject to a material removal, but to a partial optical blocking where only parts of the light emitting elements which are not covered by the light reflecting or absorbing material are arranged in the wanted distance to each other.

According to at least one aspect of the display device, the display device comprises:
a plurality of light emitting elements, and
structures having a similar or the same composition as the light emitting elements, wherein
the structures are not configured to emit light,
at least one of the structures is arranged between light emitting elements and/or
at least some of the light-emitting elements have a reduced area due to a material removal and/or,
at least some of the light-emitting elements are partially covered by a light-reflecting or absorbing material.

According to at least one aspect of the display device, at least some of the light emitting elements differ in size from each other. For example, it is possible that some light emitting elements are formed with a first number of structures and a second kind of light emitting elements is formed with a second number of structures. In this way it is possible that different light emitting elements have different sizes and shapes from each other.

According to at least one aspect of the display device, at least some of the structures are light detecting elements and/or at least some of the structures are non-optical electronic elements.

In this way at least some of the structures are, for example, used to monitor light emitting elements adjacent to them. For example, the structures are photodiodes.

In addition or alternatively, at least one of the non-optical electronic elements is configured for switching one or more of the light emitting elements. For example, such a non-optical electronic element can be a high-electron-mobility transistor or another kind of field-effect transistor.

### BRIEF DESCRIPTION OF THE DRAWINGS

In the following the here described method and the here described display device are explained in more detail with respect to exemplary embodiments and figures.

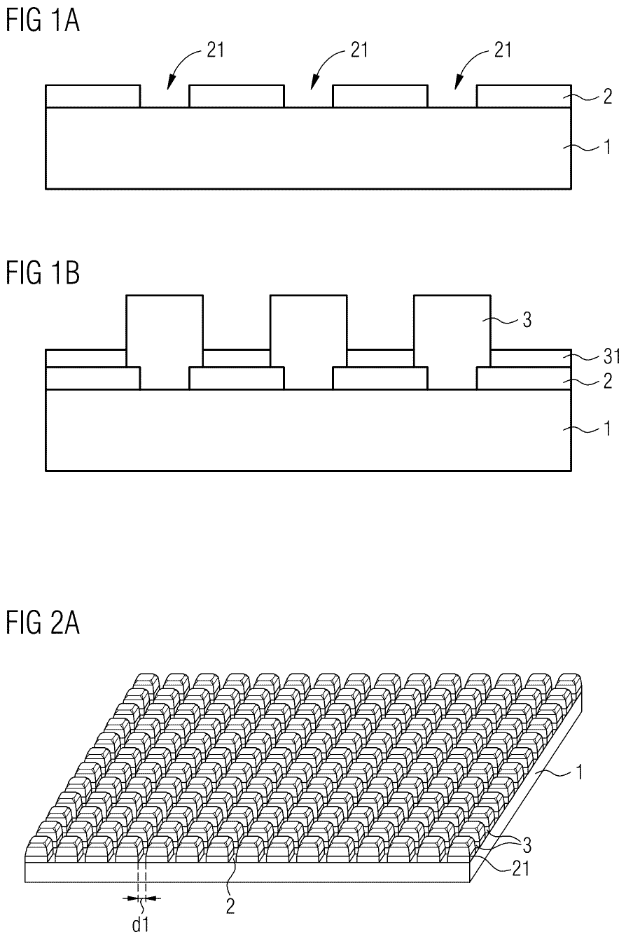

With regard to FIGS. 1A, 1B, 2A, 2B, 3, 4, 5, 6A, 6B, 6C, 7A, 7B a here described method and here described display device are explained in more detail.

In the exemplary embodiments and figures, similar or similarly acting constituent parts are provided with the same reference symbols. The elements illustrated in the figures and their size relationships among one another should not be regarded as true to scale. Rather, individual elements may be represented with an exaggerated size for the sake of better representability and/or for the sake of better understanding.

### DETAILED DESCRIPTION OF ILLUSTRATIVE EMBODIMENTS

In connection with the schematic section drawings of FIGS. 1A and 1B, a problem solved by the here described method is explained in more detail.

FIG. 1A shows a growth substrate 1 onto which a mask 2 with apertures 21 is applied. For example, the growth substrate 1 is formed as sapphire and the mask 2 is formed with SiN.

In a subsequent method step, FIG. 1B, structures 3 are epitaxially grown into the apertures 21 of the mask 2. Thereby parasitic growth 31 arises on the mask 2. This parasitic growth cause problems such as leakage current, shorting of the devices and emission of unsuitable wavelengths in the finished light emitting elements.

One method to reduce the influence of parasitic growth is to dry etch or wet etch the parasitic growth residues after the growth of the structures 3 is completed. Thereby the structures 3 have to be protected from the etching agent. This requires careful alignment and very high resolution of the lithography when forming a mask for etching. Further, the etching of the residues is frequently not perfect and residues remain.

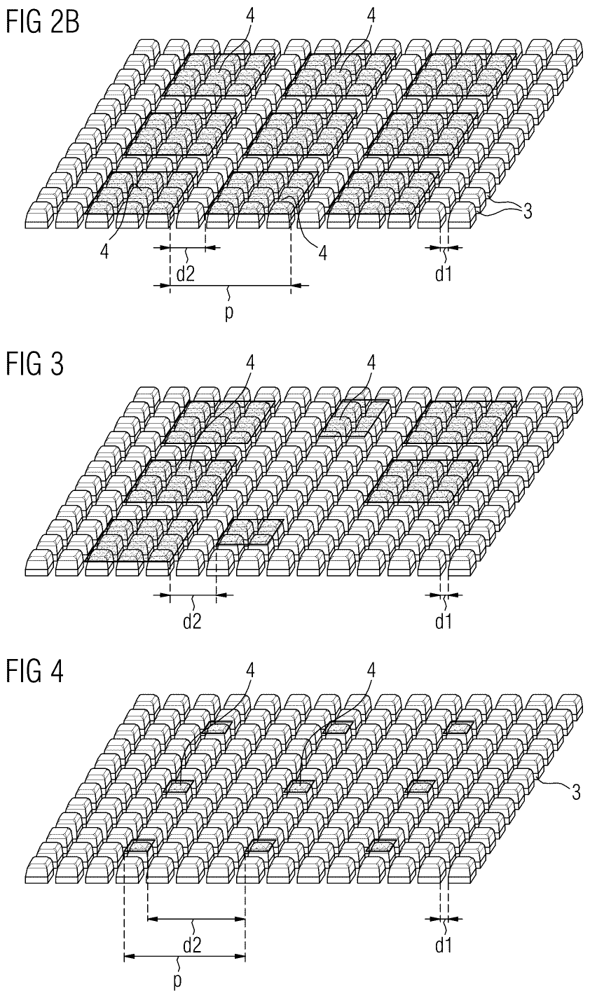

With respect to the schematic drawings of FIGS. 2A and 2B, an embodiment of a here described method is explained in more detail. FIG. 2B shows an embodiment of a here described display device.

According to the method, structures 3 are grown into the apertures 21 of a mask 2 which is placed between the apertures. Thereby adjacent apertures 21 are arranged at a first distance d1 to each other. This first distance d1 is, for example, in the range from at least 10 nm to at most 1000 nm. This is much smaller than the usual target spacing between adjacent mask openings which is between greater than 1 μm up to tens of micrometers. Due to this small distance d1 no, or nearly no, parasitic growth arises on the mask 2.

In a next method step, FIG. 2B, some of the structures 3 are processed into light emitting elements 4, for example by contacting. The distance d2 between adjacent light emitting elements 4 is greater than the first distance d1, for example in the range between at least 1 μm and 10 μm. A target pitch p is, for example, between 1 μm and 100 μm.

FIG. 2B is also a schematic representation of a here described display device with a plurality of light emitting elements 4 and structures 3 having a similar or the same composition as the light emitting elements 4 wherein the structures 3 are not configured to emit light and at least one of the structures 3 is arranged between light emitting elements 4.

In the embodiment of FIG. 2B, for example, rows and columns of structures 3 are arranged between adjacent light emitting elements 4. For example, the structures 3 which are processed to the light emitting elements 4 form sub-pixels of the light emitting elements 4. The light emitting elements 4 are, for example, LEDs or VCSELs.

FIG. 3 shows a further embodiment of a here described display device. In this embodiment the light emitting elements 4 differ in size from each other. This is achieved by combining a different number of structures 3 into the light emitting elements 4. With this it is possible to obtain an aperiodicity and/or different sizes and/or different shapes for the light emitting elements 4.

FIG. 4 shows a further embodiment of a here described display device. In this embodiment only certain structures 3, which have the wanted pitch and distance from each other, are processed into light emitting elements 4. This can be done in a periodic or in an aperiodic way.

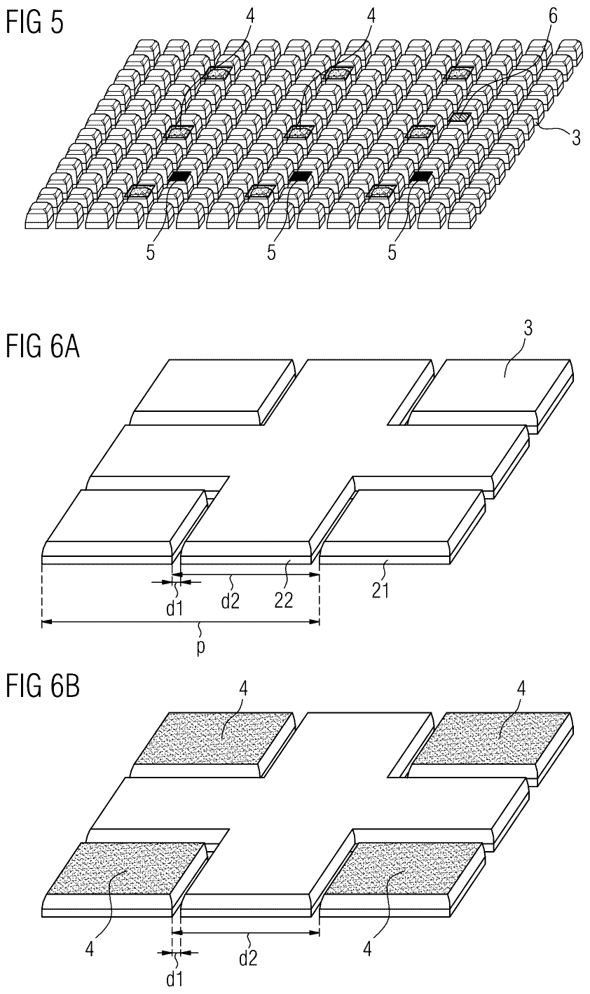

FIG. 5 shows a further embodiment of a here described display device. In this display device some of the structures 3 are non-optical electronic elements 6, such as for example high-electron-mobility transistors. In addition or alternatively, some of the structures 3 are light detecting elements 5 like, for example, photodiodes.

In connection with the schematic drawings of FIGS. 6A and 6B and 6C further embodiments of a here described method are explained in detail. FIGS. 6B and 6C additionally show further embodiments of a here described display device.

In the embodiment of FIG. 6A structures 3, which are not processed into a light emitting element 4 (also see FIG. 6B), are grown into a further aperture 22 of the mask with a greater area than the aperture 21 of the mask into which structures 3 are grown which are processed into light emitting elements 4.

As shown in connection with FIG. 6C, it is possible to process parts of the structures 3 which are grown in the aperture 22 with the greater area into light detecting elements 5 and non-optical electronic elements 6.

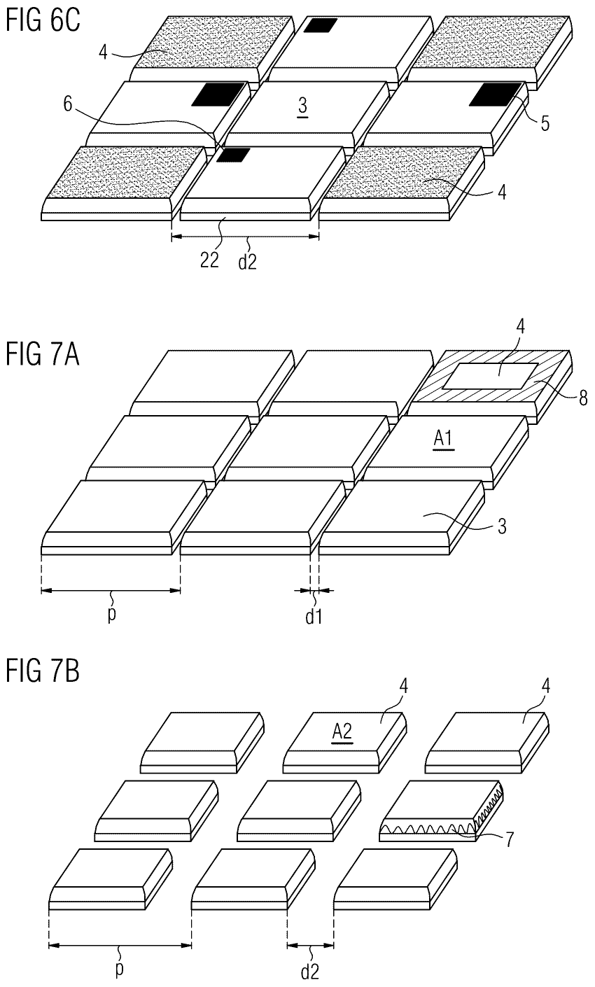

With respect to the schematic drawings of FIGS. 7A and 7B a further embodiment of a here described method is described in more detail. FIG. 7B shows a schematic drawing of an embodiment of a here described display device.

According to this method the structures 3 are grown at the target pitch p but with a smaller first distance d1 between the structures 3. In a next method step, the structures 3 are resized, for example by a material removal step like etching, such that the structures 3 are reduced in area and the reduced structures 3 are then processed into light emitting elements 4, see FIG. 7B.

As an alternative to the material removal, a light reflecting or absorbing material 8, see FIG. 7A, can be placed on the structures 3. In this way the target pixel size and spacing are obtained by optically adjusting the light emission area, for example by masking the light emission.

Further, an aperiodic distribution and/or different sizes of the light emitting elements 4 can be achieved by these methods. In the case that the structures 3 are resized in order to form the light emitting elements 4, these light emitting elements 4 show traces 7 of the removal process, in particular the etching process.

The invention is not restricted to the exemplary embodiments by the description on the basis of said exemplary embodiments. Rather, the invention encompasses any new feature and also any combination of features, which in particular comprises any combination of features in the patent claims and any combination of features in the exemplary embodiments, even if this feature or this combination itself is not explicitly specified in the patent claims or exemplary embodiments.

1.-15. (canceled)

16. A method for producing an array of light emitting elements, the method comprising:
providing a growth substrate;
applying a mask having a plurality of apertures to the growth substrate;
growing structures into the apertures; and
processing at least some of the structures into light emitting elements,
wherein adjacent apertures are arranged at a first distance to each other,
wherein adjacent light emitting elements are arranged at a second distance to each other,
wherein the second distance is greater than the first distance,
wherein at least some of the structures are reduced in area and the reduced structures are processed into light emitting elements, and
wherein the structures are reduced in area by material removal.

17. The method according to claim 16, wherein only some of the structures are processed into light emitting elements.

18. The method according to claim 16, wherein the structures are reduced in area by etching.

19. The method according to claim 16, wherein two or more of the structures are combined to form one of the light emitting elements.

20. The method according to claim 19, wherein the two or more of the structures form subpixels.

21. The method according to claim 16, wherein at least one of the structures, which is not processed into a light emitting element, is arranged between two adjacent light emitting elements.

22. The method according to claim 16, wherein at least one of the structures, which is not processed into a light emitting element, is processed into a light detecting element.

23. The method according to claim 16, wherein at least one of the structures, which is not processed into a light emitting element, is processed into a non-optical electronic element.

24. The method according to claim 16, wherein structures, which are not processed into a light emitting element, are grown into further apertures of the mask with greater areas than the apertures of the mask into which structures are grown, which are processed into light emitting elements.

25. A display device comprising:
a plurality of light-emitting elements; and
structures having a similar or the same composition as the light emitting elements,
wherein the structures are not configured to emit light,
wherein at least one of the structures is arranged between light emitting elements, and
wherein at least some of the light-emitting elements have a reduced area due to a material removal.

26. The display device according to claim 25, wherein at least some of the light-emitting elements are partially covered by a light-reflecting and/or an light absorbing material.

27. The display device according to claim 25, wherein at least some of the light-emitting elements show traces of an etching process.

28. The display device according to claim 25, wherein at least some of the light-emitting elements differ in size from each other.

29. The display device according to claim 25, wherein at least some of the structures are light detecting elements.

30. The display device according to claim 25, wherein at least some of the structures are non-optical electronic elements.
